(19) United States
(12) Patent Application Publication
(10) Pub. No.: US 2026/0255935 A1
(43) Pub. Date: Aug. 27, 2026

(54) INTERPOSER SUBSTRATE OF PACKAGE

(71) Applicant: Taiwan Semiconductor Manufacturing Company, Ltd., Hsinchu (TW)

(72) Inventors: Chen-Hsuan Tsai, Taitung City (TW); Jen-Cheng Sung, Taoyuan City (TW); Hsiao-Han Lin, Hsinchu City (TW); Chin-Chuan Chang, Hsinchu County (TW); Ying-Ching Shih, Hsinchu City (TW)

(73) Assignee: Taiwan Semiconductor Manufacturing Company, Ltd., Hsinchu (TW)

(21) Appl. No.: 19/064,656

(22) Filed: Feb. 26, 2025

(51) Int. Cl. H01L 23/00; H01L 21/768; H01L 21/78; H01L 23/31; H01L 23/48; H01L 25/11

(52) U.S. Cl. CPC H10W 20/023; H10W 90/00; H10P 54/00; H10W 20/20; H10W 70/60; H10W 74/141; H10W 90/10; H10W 90/22

(57) ABSTRACT

An interposer substrate including a local interconnect die, a dielectric layer, a first redistribution circuit layer and a second redistribution circuit layer is provided. The local interconnect die includes a substrate, through vias penetrating through the substrate, first conductive vias, a first protection layer laterally encapsulating the first conductive vias, second conductive vias, and a second protection layer laterally encapsulating the second conductive vias. The first conductive vias and the second conductive vias are disposed on opposite surfaces of the substrate, wherein the local interconnect die includes a ring-shaped indentation having a depth greater than a height of the second conductive vias. The dielectric layer laterally encapsulates the local interconnect die. The first and second redistribution circuit layers are respectively electrically connected to the first and second conductive vias. The first and second redistribution circuit layers are disposed on opposite sides of the local interconnect die and the dielectric layer.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area. These smaller electronic components also require smaller packages that occupy less area than previous packages. Examples of types of packages for semiconductors include quad flat packages (QFP), pin grid array (PGA) packages, ball grid array (BGA) packages, flip chips (FC), three-dimensional integrated circuits (3DICs), wafer level packages (WLPs), and package on package (PoP) devices, etc. multi-chip wafer level packages have developed to further reduce the physical size of a package. However, there are many challenges related to the multi-chip wafer level packages.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A through FIG. 1E are cross-sectional views schematically illustrating a method for forming local interconnect dies of a CoWoS package in accordance with some embodiments of the present disclosure.

FIG. 1F is a top view schematically illustrating the ring-shaped indentation I shown in FIG. 1E in accordance with some embodiments of the present disclosure.

FIG. 2A through FIG. 2H are cross-sectional views schematically illustrating a method for forming a CoWoS package in accordance with some embodiments of the present disclosure.

FIG. 3A through FIG. 3H are cross-sectional views schematically illustrating a method for forming a CoWoS package in accordance with some other embodiments of the present disclosure.

FIG. 4A through FIG. 4H are cross-sectional views schematically illustrating a method illustrating forming a CoWoS package in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Various embodiments of CoWoS packages including interposer substrates having at least one local interconnect die embedded therein are discussed in the followings. To solve the peeling issue of die attachment film resulted from the warpage or bulge issue of local interconnect die, in some embodiments, conductive vias distributed on back surface of the local interconnect die are laterally encapsulated by and in direct connect with die attachment glue or die attachment film, and no molding compound or polyimide layer are formed on the back surface of the local interconnect die. To solve the peeling issue of die attachment film resulted from the warpage or bulge issue of local interconnect die, in some other embodiments, a bi-layered dielectric layer is utilized to laterally encapsulate the local interconnect die, wherein a first dielectric portion of the dielectric layer laterally encapsulates a substrate and a protection layer of the local interconnect die, a second dielectric portion of the dielectric layer laterally encapsulates the conductive vias distributed on the back surface of the local interconnect die, and the second dielectric portion is in contact with the conductive vias and the back surface of the local interconnect die. The variations of the embodiments are also discussed in the followings. Throughout the various views and illustrative embodiments, like reference numbers are used to designate like elements.

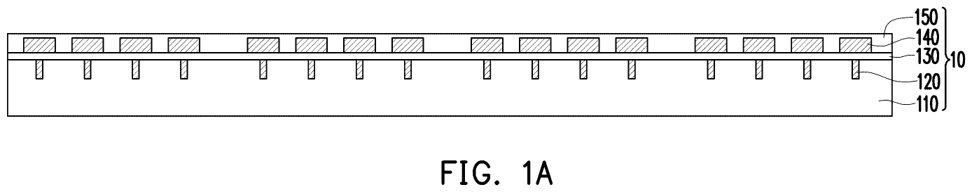

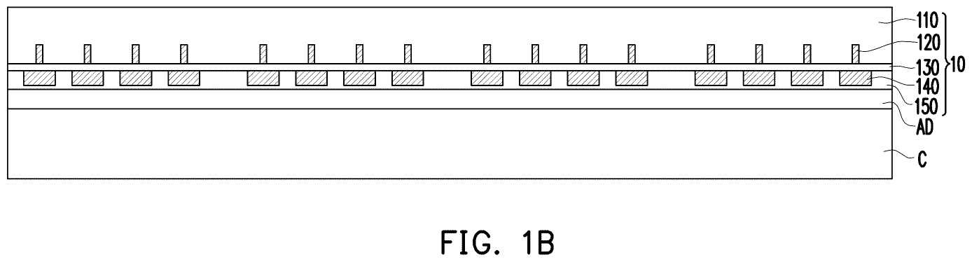

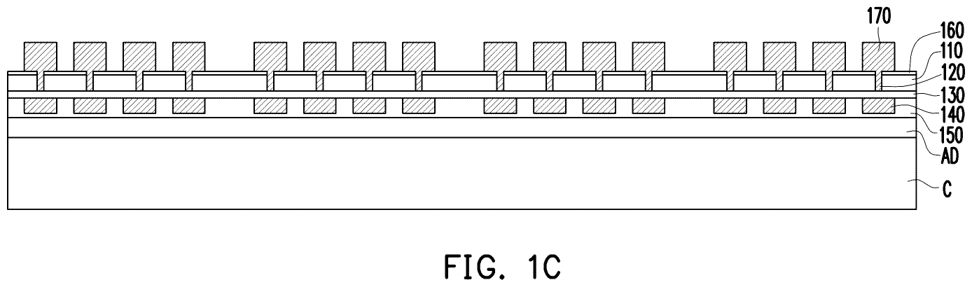

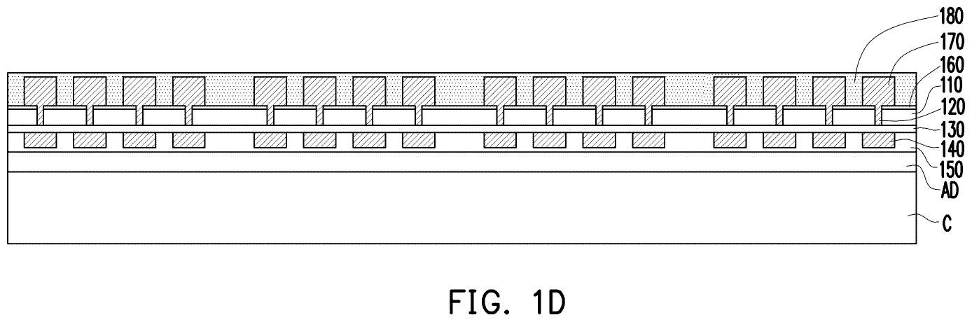

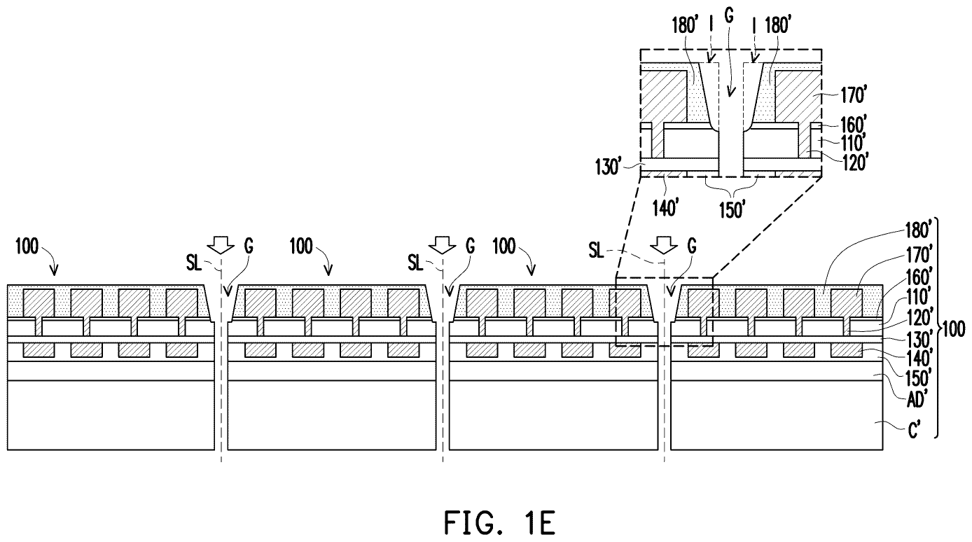

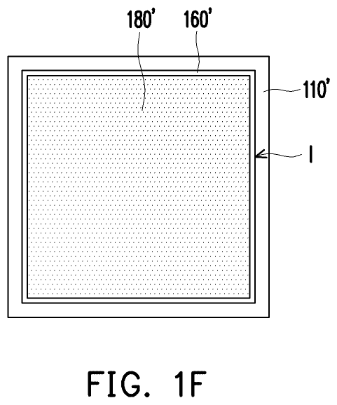

FIG. 1A through FIG. 1E are cross-sectional views schematically illustrating a method for forming local interconnect dies of a CoWoS package in accordance with some embodiments of the present disclosure. FIG. 1F is a top view schematically illustrating the ring-shaped indentation I shown in FIG. 1E in accordance with some embodiments of the present disclosure.

Referring to FIG. 1A, a semiconductor wafer 10 including a semiconductor substrate 110, through semiconductor vias 120, an interconnect structure 130, conductive vias 140, and a protection layer 150 is provided. The interconnect structure 130 is disposed on the semiconductor substrate 110. The through semiconductor vias 120 are embedded in the semiconductor substrate 110. The conductive vias 140 (e.g., front-side conductive vias) are disposed on and electrically connected to the interconnect structure 130. The protection layer 150 is disposed on the interconnect structure 130 and laterally encapsulates the conductive vias 140.

The semiconductor substrate 110 of the semiconductor wafer 10 may include a crystalline silicon wafer. The semiconductor substrate 110 may include various doped regions depending on design requirements (e.g., p-type substrate or n-type substrate). In some embodiments, the doped regions are doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. In some alternative embodiments, the semiconductor substrate 110 is made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide.

The through semiconductor vias 120 may be formed by forming recesses in the semiconductor substrate 110 by, for example, etching, milling, laser techniques, a combination thereof, and/or the like. A thin barrier layer may be conformally deposited over the front-side of the semiconductor substrate 110 and in the openings, such as by chemical vapor deposition (CVD), atomic layer deposition (ALD), physical vapor deposition (PVD), thermal oxidation, a combination thereof, and/or the like. The barrier layer may include a nitride or an oxynitride, such as titanium nitride, titanium oxynitride, tantalum nitride, tantalum oxynitride, tungsten nitride, a combination thereof, and/or the like. A conductive material is deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer may be removed from the front-side of the semiconductor substrate 110 by, for example, chemical mechanical polishing. Thus, in some embodiments, the through semiconductor vias 120 may include a conductive material and a thin barrier layer between the conductive material and the semiconductor substrate 110.

The interconnect structure 130 may include one or more dielectric layers (for example, one or more interlayered dielectric (ILD) layers, intermetal dielectric (IMD) layers, or the like) and interconnect wirings embedded in the one or more dielectric layers, and the interconnect wirings are electrically connected to the semiconductor devices (e.g., FinFETs) formed in the semiconductor substrate 110 and/or the through substrate vias 120. The material of the one or more dielectric layers may include silicon oxide (SiOₓ, where x>0), silicon nitride (SiNₓ, where x>0), silicon oxynitride (SiOₓN_{y}, where x>0 and y>0) or other suitable dielectric material. The interconnect wirings may include metallic wirings. For example, the interconnect wirings include copper wirings, copper pads, aluminum pads or combinations thereof. In some embodiments, the through substrate vias 120 may extend through one or more layers of the interconnect structure 130 and extend into the semiconductor substrate 110.

The conductive vias 140 may be copper vias formed on and electrically connected to the interconnect structure 130 through a plating process or other suitable deposition processes. The protection layer 150 may be or include a dielectric layer. The material of the protection layer 150 may be silicon oxide (SiOₓ, where x>0), silicon nitride (SiNₓ, where x>0), silicon oxynitride (SiOₓN_{y}, where x>0 and y>0) or other suitable dielectric material. The protection layer 150 may be formed by depositing a dielectric material through a chemical vapor deposition (CVD) process (e.g., a plasma enhanced CVD process or other suitable process).

As illustrated in FIG. 1A, the height of the through substrate vias 120 is less than the thickness of the semiconductor substrate 110 and the interconnect structure 130 such that the through substrate vias 120 are buried in the semiconductor substrate 110 and the interconnect structure 130. The through semiconductor vias 120 are not revealed from a back surface of the semiconductor substrate 110 at this stage. Furthermore, the thickness of the protection layer 150 is greater than the height of the conductive vias 140 such that the conductive vias 140 are entirely covered and protected by the protection layer 150. In other words, the conductive vias 140 are not revealed at this stage.

Referring to FIG. 1B, a carrier C is provided. The carrier C may be any suitable substrate that provides (during intermediary operations of the fabrication process) mechanical support for the layers over the carrier C. The carrier C may be a glass carrier, a ceramic carrier, an organic carrier, a silicon wafer or the like, which is not limited. An adhesive layer AD may be formed on the carrier C. In some embodiments, the adhesive layer AD may be film over wire (FOW), a die attachment film, or other suitable adhesive material laminated on the carrier C. The semiconductor wafer 10 is flipped and placed onto the adhesive layer AD carried by the carrier C such that the protection layer 150 of the semiconductor wafer 10 is attached onto the carrier C by the adhesive layer AD.

Referring to FIG. 1B and FIG. 1C, a thinning process or removal process is performed to remove the semiconductor substrate 110 from the back surface of the semiconductor wafer 10 until the through substrate vias 120 are revealed. In some embodiments, the above-mentioned thinning process or removal process includes a mechanical grinding process, a chemical mechanical polishing (CMP) process, combinations thereof or the like. After performing the above-mentioned thinning process or removal process, the through substrate vias 120 may slightly protrude from the back surface of the semiconductor wafer 10 due to removal selectivity. Then, a planarization layer 160 is formed on the back surface of the semiconductor substrate 110 such that an outer surface of the planarization layer 160 substantially levels with the revealed surfaces of the through substrate vias 120. The planarization layer 160 may be or include a dielectric layer. The material of the planarization layer 160 may be silicon nitride (SiNₓ, where x>0), silicon oxynitride (SiOₓN_{y}, where x>0 and y>0) or other suitable dielectric material. The planarization layer 160 may be formed by depositing a dielectric material through a CVD process (e.g., a plasma enhanced CVD process or other suitable process).

Conductive vias 170 (e.g., back side conductive vias) are then formed on the revealed surfaces of the through substrate vias 120 and the outer surface of the planarization layer 160. The conductive vias 170 are electrically connected to the interconnect structure 130 through the through substrate vias 120. The conductive vias 170 may be copper vias formed by a plating process or other suitable deposition processes.

Referring to FIG. 1D, the protection layer 180 is formed on the planarization layer 160 to laterally encapsulate the conductive vias 170. The protection layer 180 may be or include a die attachment glue or a die attachment film. The material of the die attachment glue or die attachment film may be or include epoxy resin, poly (methyl methacrylate) or other suitable dielectric material. The protection layer 180 may be formed by lamination or depositing a dielectric material through a chemical vapor deposition (CVD) process (e.g., a plasma enhanced CVD process or other suitable process). Furthermore, the thickness of the protection layer 180 is greater than the height of the conductive vias 170 such that the conductive vias 170 are entirely covered and protected by the protection layer 180. In other words, the conductive vias 170 are not revealed at this stage. At this stage, since no molding process is performed to form the protection layer 180, the warpage issue can be minimized. Furthermore, since the protection layer 180 is in direct contact with the conductive vias 170, there is not peeling issue occurred between the protection layer 180 and the conductive vias 170.

Referring to FIG. 1E, a singulation process is performed along scribe lines SL to cut the protection layer 180, the planarization layer 160, the semiconductor substrate 110, the interconnect structure 130, the adhesive layer AD and the carrier C. The singulation process includes a laser grooving process followed by a blade saw process. The laser grooving process is performed along the scribe lines SL to remove portions of the protection layer 180, portions of the planarization layer 160 and portions of the semiconductor substrate 110 such that grooves G with tapered sidewalls are formed. The grooves G may extend into the semiconductor substrate 110'. In some embodiments, the depth of the grooves G is greater than the sum of the height of the conductive vias 170′ and the thickness of the planarization layer 160′. For example, the depth of the grooves G is greater than the sum of the thickness of protection layer 180′ and the thickness of the planarization layer 160′. The above-mentioned blade saw process is performed along the scribe lines SL to cut portions of the semiconductor substrate 110 underlying the grooves G, portions of the interconnect structure 130, portions of the adhesive layer AD and portions of the carrier C such that the singulation process is accomplished. After performing the singulation process, singulated local interconnect dies 100 (e.g., local silicon interconnect (LSI) dies) are obtained.

Each one of the local interconnect dies 100 respectively includes a semiconductor substrate 110′, through substrate vias 120′ penetrating through the semiconductor substrate 110′, an interconnect structure 130′ disposed on the semiconductor substrate 110′, conductive vias 140', a protection layer 150′ laterally encapsulating the conductive vias 140′, conductive vias 170′, and a protection layer 180′ laterally encapsulating the conductive vias 170′. The conductive vias 140′ and the protection layer 150′ are disposed on a first surface (e.g., a front surface) of the semiconductor substrate 110′ while the conductive vias 170′ and the protection layer 180′ are disposed on a second surface (e.g., a back surface) of the semiconductor substrate 110′. The semiconductor substrate 110′ may be or include a silicon substrate including active components (e.g., transistors or the like) and passive components (e.g., resistors, capacitors, inductors, or the like) formed therein. The through substrate vias 120′, the active components and the passive components are formed in the semiconductor substrate 110′ through front end of line (FEOL) fabrication processes of the semiconductor wafer. The interconnect structure 130′ is disposed on the semiconductor substrate 110′. The interconnect structure 130′ may include interconnect wirings (e.g., copper interconnect wirings) and dielectric layer stacked alternately, wherein the interconnect wirings of the interconnect structure 130′ are electrically connected to the through substrate vias 120′, the active components and/or the passive components in the semiconductor substrate 110′. The interconnect structure 130′, the conductive vias 140′ and the protection layer 150′ are formed through back end of line (BEOL) fabrication processes of semiconductor wafer. The topmost interconnect wirings may include conductive pads, and the conductive pads may be aluminum pads, copper pads, or other suitable metallic pads. The interconnect structure 130′ may further include a passivation layer, wherein the conductive pads are partially covered by the passivation layer. In other words, the conductive pads are partially revealed from the openings defined in the passivation layer. The passivation may be a silicon oxide layer, a silicon nitride layer, a silicon oxy-nitride layer, or a dielectric layer formed by other suitable inorganic dielectric materials. The interconnect structure 130′ may further include a post-passivation layer formed over the passivation layer, wherein the post-passivation layer covers the passivation layer and the conductive pads, the post-passivation layer includes a plurality of contact openings, and the conductive pads are partially revealed from the contact openings defined in the post passivation layer. The post-passivation layer may be a polyimide (PI) layer, a PBO layer, or a dielectric layer formed by other suitable organic dielectric materials. In some embodiments, the post-passivation layer is omitted.

As illustrated in FIG. 1E, each one of the local interconnect dies 100 may further includes an adhesive layer AD′ and a carrier C′, wherein the protection layer 150′ is attached to the carrier C′ through the adhesive layer AD′. In some embodiments, the sidewalls of the protection layer 150′ substantially aligned with the sidewalls of the adhesive layer AD′ and the sidewalls of the carrier C′.

Furthermore, as illustrated in FIG. 1E and FIG. 1F, each one of the local interconnect dies 100 respectively includes a ring-shaped indentation I having a depth greater than the height of the conductive vias 170′. In some embodiments, sidewalls of the protection layer 150′ substantially align with sidewalls of the semiconductor substrate 110′, and the sidewalls of the protection layer 150′ laterally offset from sidewalls of the protection layer 180′. In some embodiments, the sidewalls of the protection layer 150′ and the sidewalls of the semiconductor substrate 110′ includes vertical sidewalls, and the sidewalls of the protection layer 180′ include tapered sidewalls. In some embodiments, the local interconnect die 100 further includes a planarization layer 160′ disposed between the semiconductor substrate 110′ and the conductive vias 170′, the through substrate vias 120′ penetrate through the semiconductor substrate 110′ and the planarization layer 160′, and sidewalls of the planarization layer 160′ include tapered sidewalls. In some embodiments, the ring-shaped indentation I extends into the semiconductor substrate 110′. In some embodiments, the depth of the ring-shaped indentation I is greater than the sum of the height of the conductive vias 170′ and the thickness of the planarization layer 160′. For example, the depth of the ring-shaped indentation I is greater than the sum of the thickness of the protection layer 180′ and the thickness of the planarization layer 160′. In some embodiments, the top end of the sidewall of the protection layer 180′ laterally offsets from the top end of the sidewall of the semiconductor substrate 110′ by a distance smaller ranging from about 2 micrometers to about 10 micrometers, and the bottom end of the sidewall of the protection layer 180′ laterally offsets from the top end of the sidewall of the semiconductor substrate 110′ by a distance smaller than or equal to 5 micrometers. In some embodiments, the bottom end of the sidewall of the protection layer 180′ is located at a first level height, the top end of the sidewall of the semiconductor substrate 110′ is located at a second level height lower than the first level height, and the level height difference between the first level height and the second level height may be equal to or smaller than 5 micrometers.

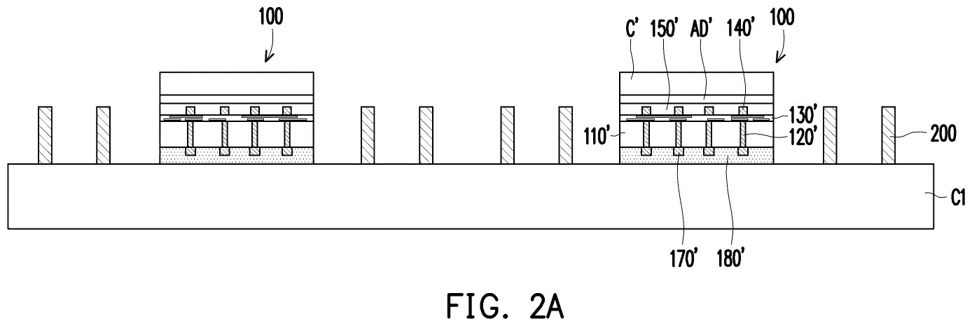

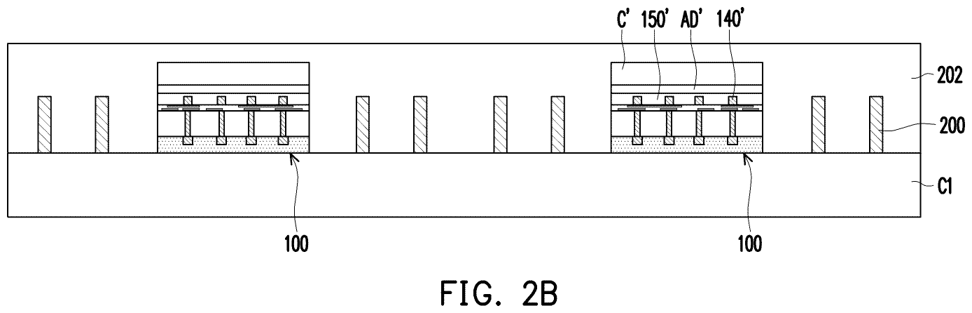

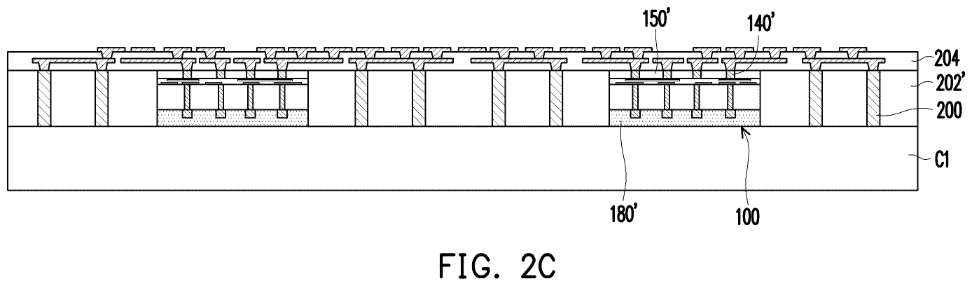

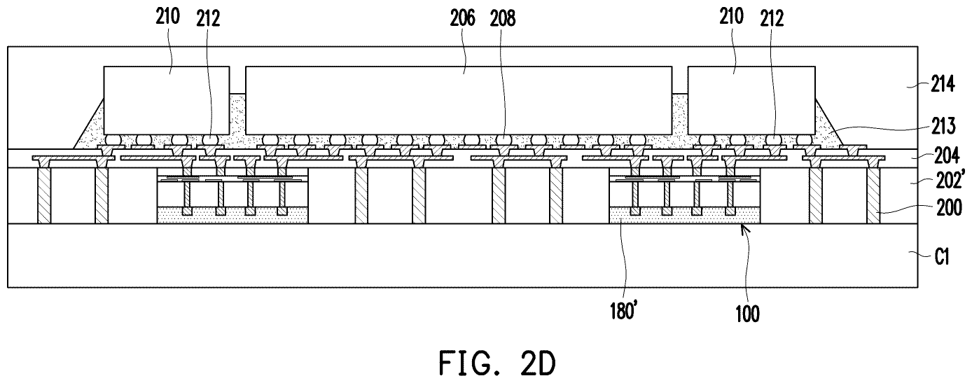

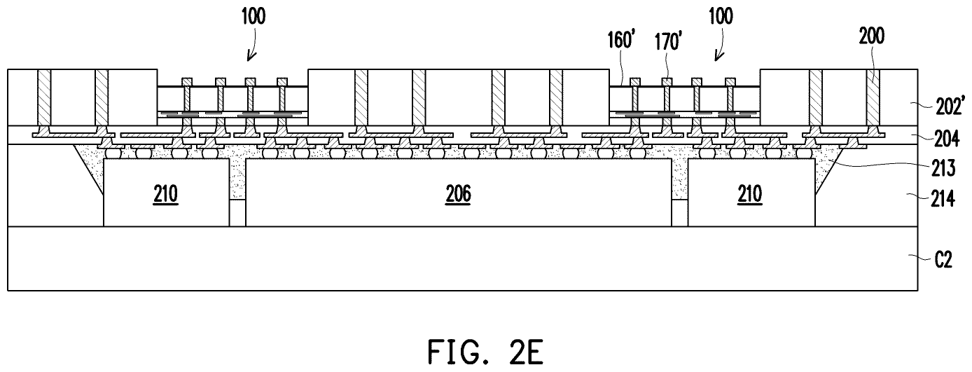

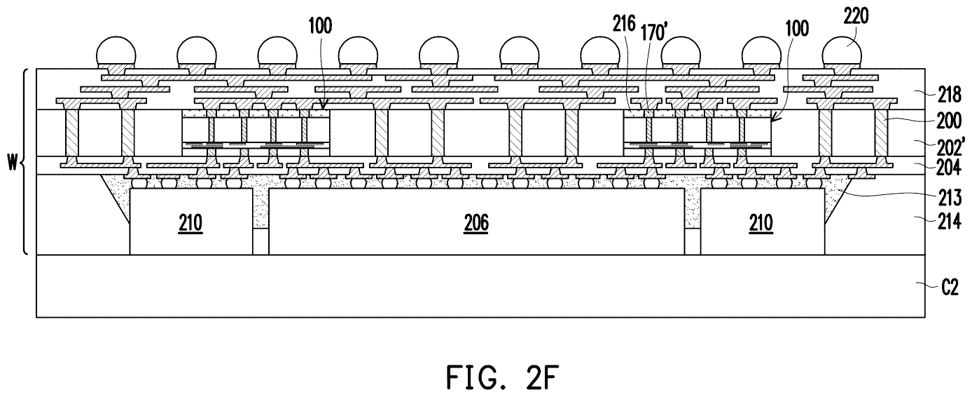

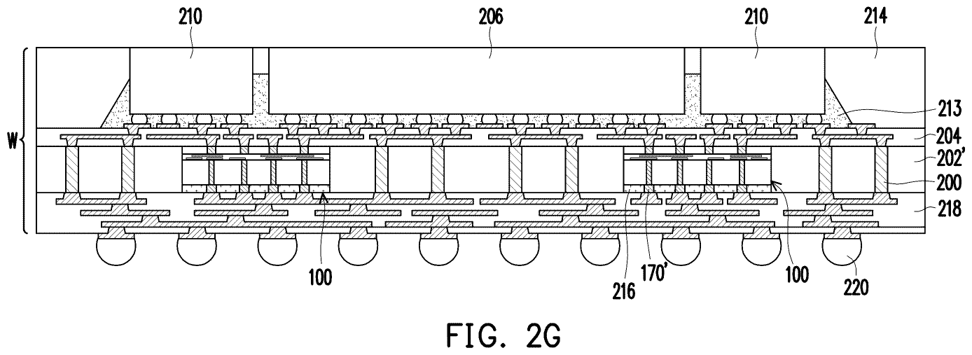

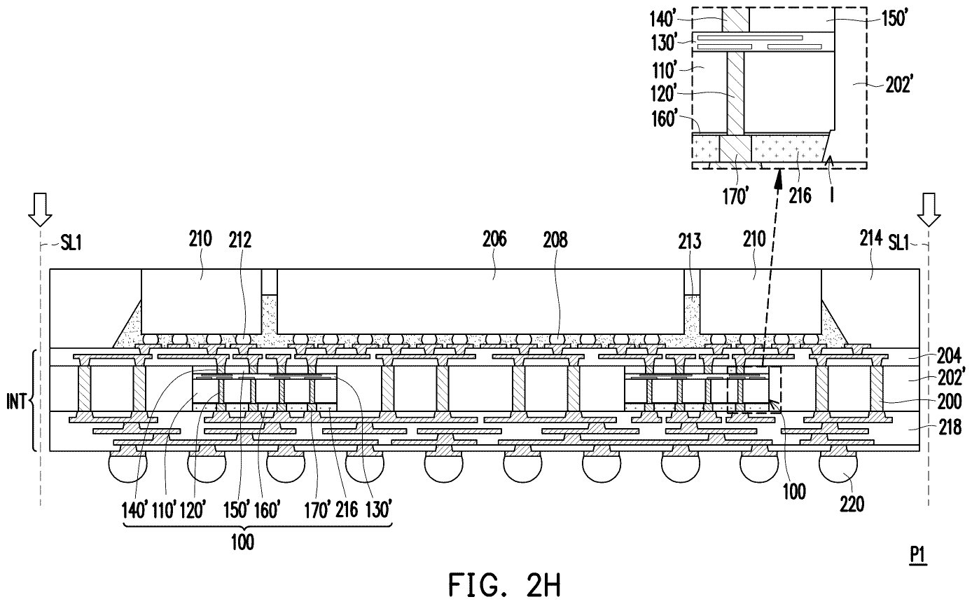

FIG. 2A through FIG. 2H are cross-sectional views schematically illustrating a method for forming a CoWoS package in accordance with some embodiments of the present disclosure.

Referring to FIG. 2A, a carrier C1 is provided. In some embodiments, the carrier C1 having a de-bonding layer (not shown) formed thereon is provided. In some embodiments, the carrier C1 is a wafer form glass substrate, the de-bonding layer is a light-to-heat conversion (LTHC) release layer formed on the wafer form glass substrate. The material of the carrier C1 and the material of the de-bonding layer formed on the carrier C1 are not limited in the present embodiment. In some alternative embodiments, the de-bonding layer formed on the carrier C1 may be omitted. Furthermore, through insulator vias 200 are formed on the carrier C1. In some embodiments, the through insulator vias 200 are copper pillars or other conductive pillars. In some embodiments, the through insulator vias 200 may be formed on the carrier C1 through a plating process or other suitable deposition processes. In some other embodiments, the through insulator vias 200 may be pre-formed and placed onto the carrier C1.

In some embodiments, after forming the through insulator vias 200, a plurality of local interconnect dies 100 as illustrated in FIG. 1E are picked and placed over the carrier C1. The local interconnect dies 100 disposed may be arranged side-by-side over the carrier C1. The local interconnect dies 100 disposed over the carrier C1 may be substantially identical in thickness. As illustrated in FIG. 2A, the protection layer 180′ of the local interconnect dies 100 is attached onto the carrier C1, and the thickness of the local interconnect dies 100 is greater than the height of the through insulator vias 200.

Referring to FIG. 2B and FIG. 2C, an insulating material 202 may be formed over the carrier C1 by an over-molding process or a film deposition process. The insulating material 202 entirely covers the local interconnect dies 100 and the through insulator vias 200. As illustrated in FIG. 2B, the thickness of the insulating material 202 is greater than the thickness of the local interconnect dies 100A and the height of the through insulator vias 200. After performing the over-molding process or film deposition process, as illustrated in FIG. 2B and FIG. 2C, a thinning process or removal process is performed to partially remove the insulating material 202, the carriers C′, the adhesive layer AD′ and portions of the protection layer 150′ until top surfaces of the through insulator vias 200 and top surfaces of the conductive vias 140′ are revealed. In some embodiments, the above-mentioned thinning process or removal process of the insulating material 202 includes a mechanical grinding process, a chemical mechanical polishing (CMP) process, combinations thereof or the like. After performing the thinning process or removal process of the insulating material 202, an insulating encapsulation 202′ is formed over the carrier C1 to laterally encapsulate the local interconnect dies 100 and the through insulator vias 200. In some embodiments, the material of the insulating encapsulation 202′ includes molding compound, underfill material, molded underfill material or other suitable dielectric materials. For example, the material of the insulating encapsulation 202′ includes epoxy resin.

After performing the thinning process or removal process of the insulating material 202, as shown in FIG. 2C, the top surface of the insulating encapsulation 202′ may substantially level with the top surfaces of the conductive vias 140′, the top surfaces of the protection layers 150′ and the top surfaces of the through insulator vias 200. In some alternative embodiments, due to selectivity, the top surface of the insulating encapsulation 202′ may be slightly higher than or slightly lower than the top surfaces of the conductive vias 140′, the top surfaces of the protection layers 150′ and the top surfaces of the through insulator vias 200.

A front-side redistribution circuit layer 204 is formed over the local interconnect dies 100, the through insulator vias 200 and the insulating encapsulation 202′. The front-side redistribution circuit layer 204 is formed on and in contact with the top surfaces of the through insulator vias 200, the top surface of the insulating encapsulation 202′, the top surfaces of the conductive vias 140′ and the top surfaces of the protection layers 150′. The front-side redistribution circuit layer 204 may include multiple layers of redistribution wirings and multiple insulating layers stacked alternately, wherein the redistribution wirings are embedded in the insulating layers, and the redistribution wirings are electrically connected to the conductive vias 140′ and the through insulator vias 200. The redistribution wirings of the front-side redistribution circuit layer 204 may be or include copper redistribution wirings, and the insulating layers of the front-side redistribution circuit layer 204 may be or include polyimide (PI), PBO, silicon oxide layers, silicon nitride layers, silicon oxy-nitride layers, combinations thereof or the like.

Referring to FIG. 2D, at least one semiconductor die 206 having bumps 208 formed thereon and memory devices 210 having bumps 212 are provided. The semiconductor 206 and the memory devices 210 are mounted onto the front-side redistribution circuit structure 204 and electrically connected the front-side redistribution circuit structure 204 through the bumps 208 and the bumps 212, respectively. In some embodiments, the semiconductor die 206 may be a System-on-Chip (SoC) die, and the memory devices 210 may be high bandwidth memory (HBM) cubes including stacked memory dies.

As illustrated in FIG. 2D, an underfill 213 is formed between the front-side redistribution circuit structure 204 and the semiconductor die 206 as well as the front-side redistribution circuit structure 204 and the memory devices 210. The underfill 213 laterally encapsulates the bumps 208 and the bumps 212. The material of the underfill 213 may be or include non-conductive paste (NCP), non-conductive film (NCF), molded underfill (MUF) material or other suitable materials. An insulating encapsulation 214 is then formed on the front-side redistribution circuit structure 204 to cover the semiconductor die 206, the memory devices 210 and the underfill 213. The insulating encapsulation 214 may be formed by an over-molding process or a film deposition process, and the material of the insulating encapsulation 214 may include molding compound, molded underfill (MUF) material or other suitable dielectric materials. For example, the insulating encapsulation 214 includes epoxy resin. In some embodiments, the material of the insulating encapsulation 214 is the same as that of the insulating encapsulation 202′. In some alternative embodiments, the material of the insulating encapsulation 214 is different from that of the insulating encapsulation 202′ or that of the underfill 213. The thickness of the insulating encapsulation 202′ may be less than the thickness of the insulating encapsulation 214.

Referring to FIG. 2D and FIG. 2E, the resulted structure illustrated in FIG. 2D is flipped upside down and mounted onto a carrier C2 such that the insulating encapsulation 214 is bonded to the carrier C2. A de-bonding process is performed such that the carrier C1 is de-bonded from the local interconnect dies 100, the through insulator vias 200 and the insulating encapsulation 202′. After performing the de-bonding process of the carrier C1, the protection layers 180′ of the local interconnect dies 100 are revealed.

As illustrated in FIG. 2E, the protection layers 180′ are removed such that the conductive vias 170′ and the planarization layers 160′ of the local interconnect dies 100 are revealed. In some embodiments, the protection layers 180′ are removed by an etch process or other suitable removal processes such that cavities are formed.

Referring to FIG. 2E and FIG. 2F, protection layers 216 are formed on the planarization layers 160′ of the local interconnect dies 100 such that the protection layers 216 laterally encapsulates the conductive vias 170′, and the conductive vias 170′ penetrate through the protection layers 216. The protection layers 216 may be formed by a printing process followed by a planarization process. The printing process for forming the protection layers 216 may include screen printing, and the planarization process for forming the protection layers 216 may include a mechanical grinding process, a CMP process, combinations thereof or the like. For example, polyimide material or underfill material may be formed in the cavities through a screen-printing process followed by a planarization process. During the planarization process for forming the protection layers 216, the insulating encapsulation 202′ and the through insulator vias 200 are partially removed until the conductive vias 170′ are revealed. In some embodiments, the top surfaces of the protection layers 216 and the top surfaces of the conductive vias 170′ may substantially level with the top surface of the insulating encapsulation 202′ and the top surfaces of the through insulator vias 200.

Compared with the protection layers 180′ illustrated in FIG. 2D, the protection layers 216 include tapered sidewalls, the tapered sidewalls of the protection layers 216 substantially coincides with the lower portions of the tapered sidewalls of the protection layers 180′. The sidewalls of the protection layers 216 (shown in FIG. 2F) and the lower portion of the sidewalls of the protection layers 180′ (shown in FIG. 2D) are identical in slope. In other words, after forming the protection layers 216, the ring-shaped indentation I (shown in FIG. 1E) of each of the local interconnect dies 100 remains. Furthermore, the thickness of the protection layers 216 is less than the thickness of the protection layer 180′. In other words, the conductive vias 170′ penetrate through the protection layers 216, and the thickness of the protection layers 216 substantially equals to the height of the conductive vias 170′. In some other embodiments, the thickness of the protection layers 216 is slightly greater than or slight less than the height of the conductive vias 170′.

As illustrated in FIG. 2F, a back-side redistribution circuit layer 218 is formed to on the conductive vias 170′, the protection layers 216, the through insulator vias 200 and the insulating encapsulation 202′. The back-side redistribution circuit layer 218 may include multiple layers of redistribution wirings and multiple insulating layers stacked alternately, wherein the redistribution wirings are embedded in the insulating layers, and the redistribution wirings are electrically connected to the conductive vias 170′ and the through insulator vias 200. The redistribution wirings of the back-side redistribution circuit layer 218 may be or include copper redistribution wirings, and the insulating layers of the back-side redistribution circuit layer 218 may be PI, PBO, silicon oxide layers, silicon nitride layers, silicon oxy-nitride layers, combinations thereof or the like. In some embodiments, the back-side redistribution circuit layer 218 is electrically connected to the front-side redistribution circuit layer 204 through the local interconnect dies 100 and the through insulator vias 200.

Conductive terminals 220 are formed on the back-side redistribution circuit layer 218. The conductive terminals 220 are electrically connected to the redistribution wirings of the back-side redistribution circuit layer 218. The conductive terminals 220 may be or include Controlled Collapse of Chip Connection bumps (C4 bumps) or solder balls (e.g., lead free solder balls) arranged in array. After forming the back-side redistribution circuit layer 218 and the conductive terminals 220, a reconstructed wafer W is formed on the carrier C1.

Referring to FIG. 2F and FIG. 2G, the reconstructed wafer W is de-bonded from the carrier C1 and a planarization process is performed to partially remove the insulating encapsulation 214 until the semiconductor die 206 and the memory devices 210 are revealed. The planarization process for partially removing the insulating encapsulation 214 may include a mechanical grinding process, a CMP process, combinations thereof or the like. After performing the planarization process, the top surface of the insulating encapsulation 214 substantially levels with the revealed surfaces of the semiconductor die 206 and the memory devices 210.

Referring to FIG. 2G and FIG. 2H, a singulation process (i.e. a wafer saw process) is performed along the scribe line SL1 such that the reconstructed wafer W (shown in FIG. 2G) is singulated into multiple package structures P1 (shown in FIG. 2H). The singulation process for the reconstructed wafer W may be or include a blade saw process. After obtaining the singulated package structures P1, the package structures P1 may be placed on and electrically connected to a wiring substrate (e.g., a printed circuit substrate) through the conductive terminals 220 such that a CoWoS package including the package structure P1 can be formed.

As illustrated in FIG. 2H, the package structure P1 includes an interposer substrate INT, a semiconductor die 206 and memory devices 210. The semiconductor die 206 and the memory devices 210 are mounted on and electrically connected to the interposer substrate INT. The interposer substrate INT includes local interconnect dies 100, a dielectric layer (i.e., the insulating encapsulation 202′), a front-side redistribution circuit layer 204 and a back-side redistribution circuit layer 218. The local interconnect dies 100 each includes a semiconductor substrate 110′, through substrate vias 120′ penetrating through the semiconductor substrate 110′, an interconnect structure 130′, conductive vias 140′, a protection layer 150′ laterally encapsulating the conductive vias 140′, conductive vias 170′, and a protection layer 216 laterally encapsulating the conductive vias 170′. The conductive vias 140′ and the protection layer 150′ are disposed on a first surface of the semiconductor substrate 110′. The conductive vias 170′ and the protection layer 216 are disposed on a second surface of the semiconductor substrate 110′. The insulating encapsulation 202′ laterally encapsulates the local interconnect dies 100. The front-side redistribution circuit layer 204 is electrically connected to the conductive vias 140′. The back-side redistribution circuit layer 218 is electrically connected to the conductive vias 170′, wherein the front-side redistribution circuit layer 204 and the back-side redistribution circuit layer 218 are disposed on opposite sides of the local interconnect dies 100 and the insulating encapsulation 202′. In some embodiments, sidewalls of the protection layer 150′ substantially align with sidewalls of the semiconductor substrate 110′, and the sidewalls of the protection layer 150′ laterally offset from sidewalls of the protection layer 216. In some embodiments, the sidewalls of the protection layer 150′ and the sidewalls of the semiconductor substrate 110′ includes vertical sidewalls, and the sidewalls of the protection layer 216 include tapered sidewalls. In some embodiments, the thickness of the protection layer 150′ is substantially equal to the height of the conductive vias 140′, and the thickness of the protection layer 216 is substantially equal to the height of the conductive vias 170′. In some embodiments, the local interconnect dies 100 each further includes a planarization layer 160′ disposed between the semiconductor substrate 110′ and the conductive vias 170′, the through substrate vias 120′ penetrate through the semiconductor substrate 110′ and the planarization layer 160′, and the sidewalls of the planarization layer 160′ include tapered sidewalls. In some embodiments, the ring-shaped indentation I extends into the semiconductor substrate 110′. In some embodiments, the depth of the ring-shaped indentation I is greater than the sum of the height of the conductive vias 170′ and the thickness of the planarization layer 160′. In some embodiments, the insulating encapsulation 202′ is laterally spaced apart from the conductive vias 170′ by the protection layer 216.

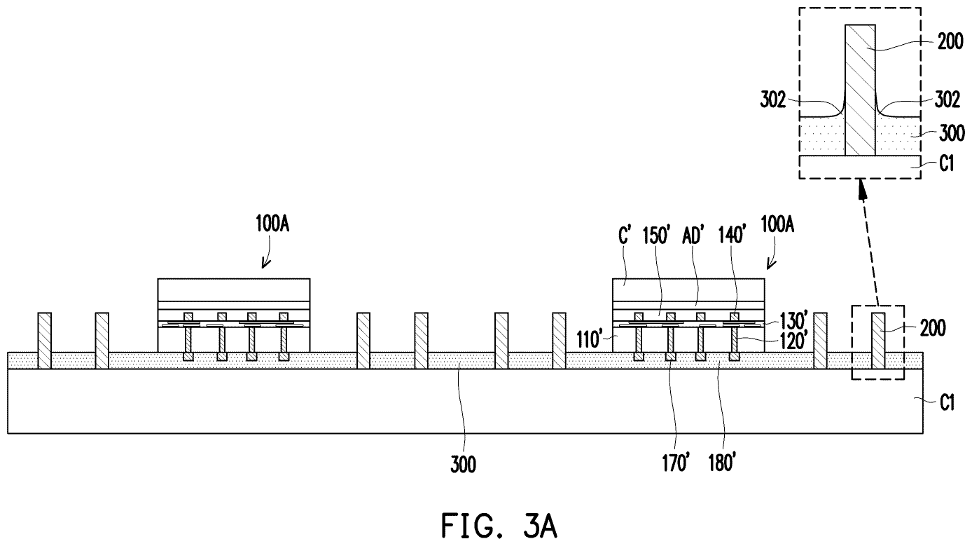

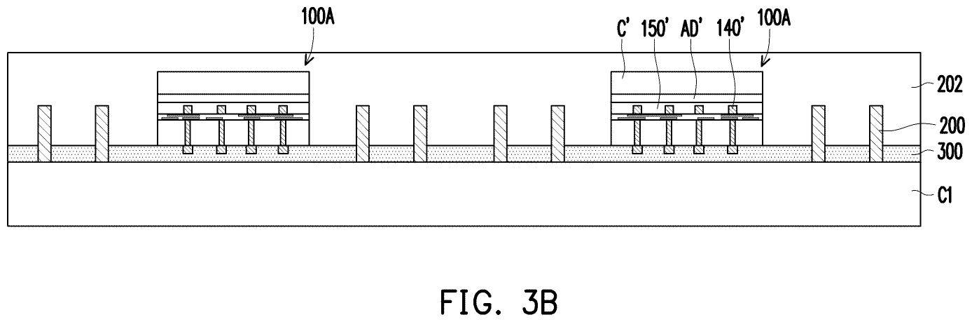

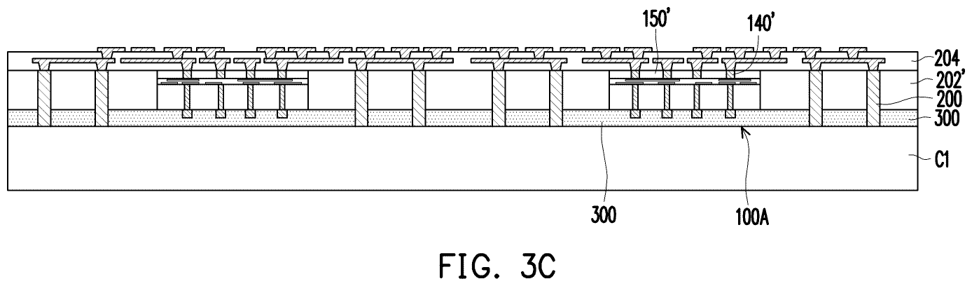

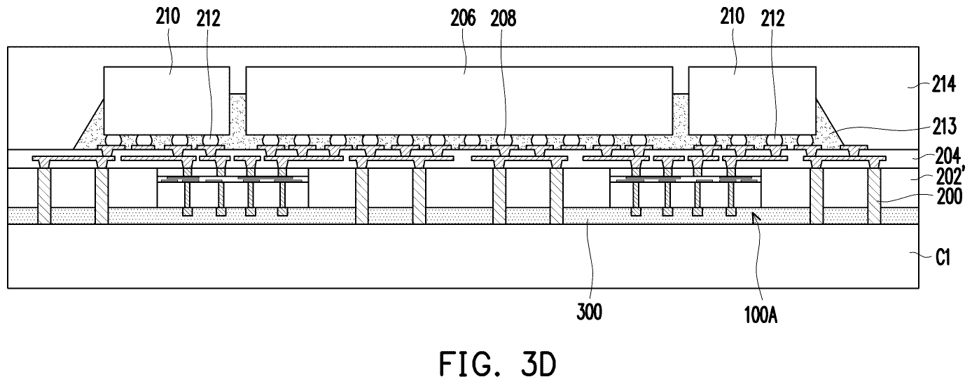

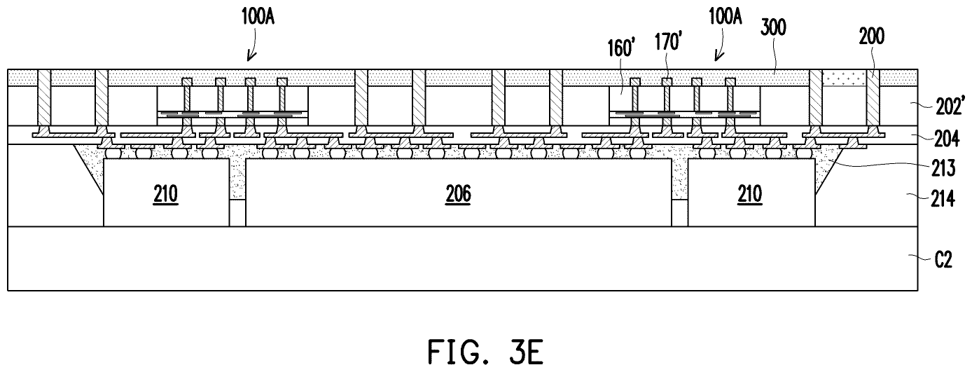

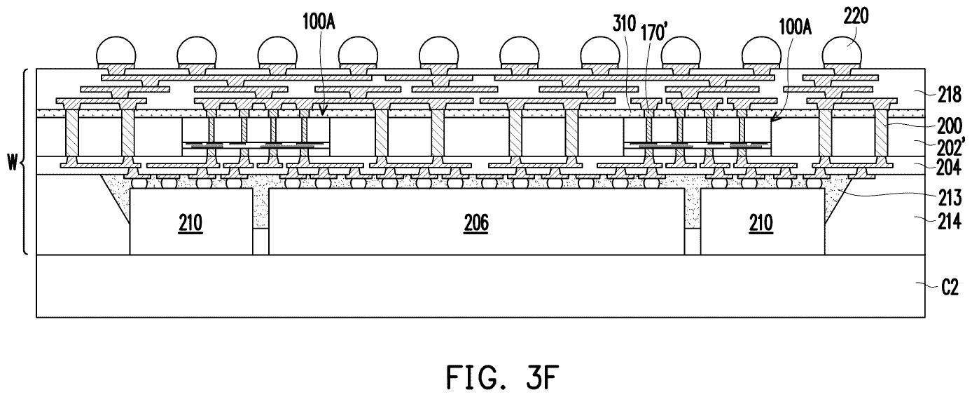

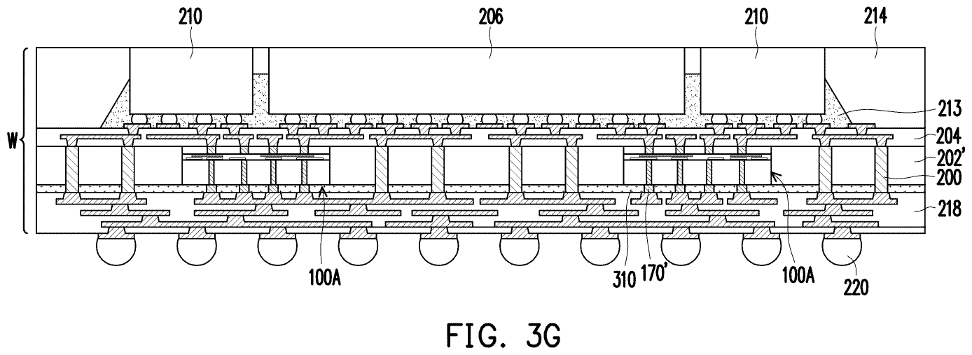

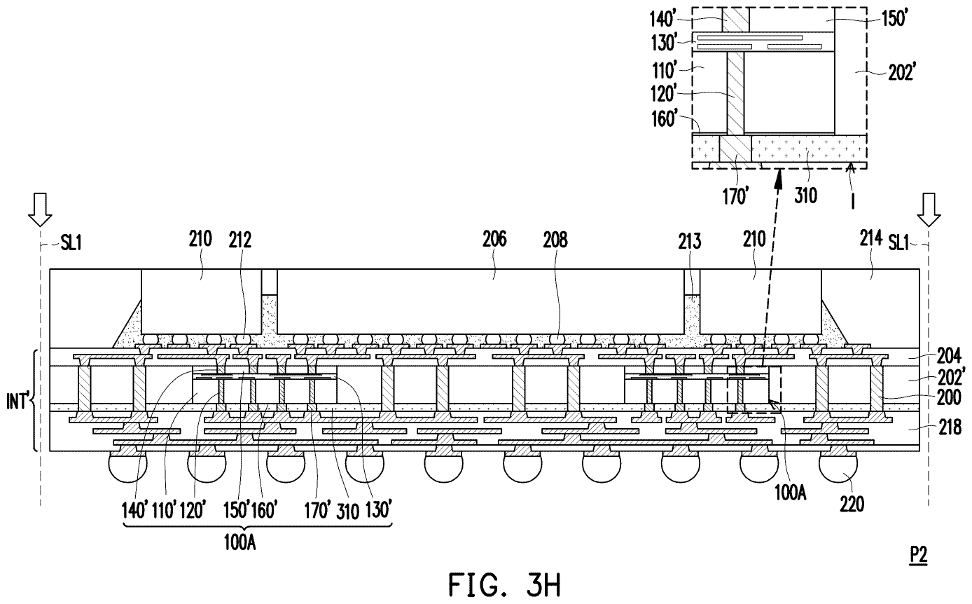

FIG. 3A through FIG. 3H are cross-sectional views schematically illustrating a method for forming a CoWoS package in accordance with some other embodiments of the present disclosure.

Referring to FIG. 3A, a carrier C1 is provided. The carrier C1 having a die attachment film or a die attachment glue 300 formed thereon is provided. In some embodiments, the carrier C1 is a wafer form glass substrate. The material of the carrier C1 is not limited in the present embodiment. Furthermore, through insulator vias 200 are formed on the carrier C1, the through insulator vias 200 penetrate through the die attachment film 300, and the through insulator vias 200 protrude from the top surface of the die attachment film 300. In some embodiments, the through insulator vias 200 are copper pillars or other conductive pillars. In some embodiments, the through insulator vias 200 may be formed on the carrier C1 through a plating process or other suitable deposition processes. In some other embodiments, the through insulator vias 200 may be pre-formed and placed onto the carrier C1. In some embodiments, the through insulator vias 200 may be formed prior to the formation of the die attachment film 300 such that the through insulator vias 200 may pierce through the die attachment film 300. As illustrated in the enlarged region in FIG. 3A, the die attachment film 300 may include protruding portions 302 laterally surrounding the through insulator vias 200. Furthermore, the protruding portions 302 of the die attachment film 300 may have tapered sidewalls.

After forming the die attachment film 300 and the through insulator vias 200, a plurality of local interconnect dies 100A are picked and placed over the die attachment film 300 carried by the carrier C1. The local interconnect dies 100A disposed may be arranged side-by-side on the die attachment film 300. The local interconnect dies 100A disposed on the die attachment film 300 may be substantially identical in thickness. As illustrated in FIG. 3A, the local interconnect dies 100A of the present embodiment is similar to the local interconnect dies 100 as illustrated in FIG. 1E except that the local interconnect dies 100A does not include the protection layer 180′, and the conductive vias 170′ of the local interconnect dies 100A are embedded in and in direct contact with the die attachment film 300. As illustrated in FIG. 3A, the conductive vias 170′ of the local interconnect dies 100A protrude into the die attachment film 300 and are spaced apart from the carrier C1 by the die attachment film 300, and the thickness of the local interconnect dies 100A is greater than the height of the through insulator vias 200. In some other embodiments, the die attachment film 300 may extend to cover lower portions of the sidewalls of the local interconnect dies 100A.

The processes illustrated in FIG. 3B through FIG. 3D are similar to the processes illustrated in FIG. 2B through FIG. 2D, and the details are thus omitted.

Referring to FIG. 2E and FIG. 3E, the process illustrated in FIG. 3E is similar the process illustrated in FIG. 2E except that the die attachment film 300 is removed and a protection layer 310 is formed. The protection layer 310 is formed from the die attachment film 300. The protection layer 310 covers the insulating encapsulation 202′ and the local interconnect dies 100A. Furthermore, the protection layer 310 laterally encapsulates upper portions of the through insulator vias 200. The conductive vias 170′ are covered by the protection layer 310. In other words, the conductive vias 170′ are not revealed at this stage.

The processes illustrated in FIG. 3F through FIG. 3H are similar to the processes illustrated in FIG. 2F through FIG. 2H, and the details are thus omitted.

As illustrated in FIG. 3H, the package structure P2 includes an interposer substrate INT′, a semiconductor die 206 and memory devices 210. The semiconductor die 206 and the memory devices 210 are mounted on and electrically connected to the interposer substrate INT′. The interposer substrate INT′ includes local interconnect dies 100A, a dielectric layer including the insulating encapsulation 202′ and the protection layer 310, a front-side redistribution circuit layer 204 and a back-side redistribution circuit layer 218. The local interconnect die 100A each includes a semiconductor substrate 110′, through substrate vias 120′ penetrating through the semiconductor substrate 110′, conductive vias 140′, a protection layer 150′ laterally encapsulating the conductive vias 140′, and conductive vias 170′. The conductive vias 140′and the protection layer 150′ are disposed on a first surface of the semiconductor substrate 110′, and the conductive vias 170′ are disposed on a second surface of the semiconductor substrate 110′. A first dielectric portion (i.e., the insulating encapsulation 202′) of the dielectric layer laterally encapsulates the semiconductor substrate 110′ and the protection layer 150′, a second dielectric portion (i.e., the protection layer 310) of the dielectric layer laterally encapsulates the conductive vias 170′, and the second dielectric portion (i.e., the protection layer 310) is in contact with the conductive vias 170′ and the second surface of the semiconductor substrate 110′. The front-side redistribution circuit layer 204 is electrically connected to the conductive vias 140′. The back-side redistribution circuit layer 218 is electrically connected to the conductive vias 170′, wherein the front-side redistribution circuit layer 204 and the back-side redistribution circuit layer 218 are disposed on opposite sides of the local interconnect dies 100A and the dielectric layer (i.e., the insulating encapsulation 202′ and the protection layer 310). In some embodiments, the first dielectric portion (i.e., the insulating encapsulation 202′) and the second dielectric portion (i.e., the protection layer 310) are different in material. In some embodiments, sidewalls of the first dielectric portion (i.e., the insulating encapsulation 202′) substantially align with sidewalls of the second dielectric portion (i.e., the protection layer 310). In some embodiments, the second dielectric portion (i.e., the protection layer 310) is wider than the first protection layer (i.e., the insulating encapsulation 202′). In some embodiments, sidewalls of the front-side redistribution circuit layer 204 substantially align with sidewalls of the second dielectric portion (i.e., the protection layer 310). In some embodiments, the interposer substrate INT′ further includes through insulator vias 200 penetrating through the first dielectric portion (i.e., the insulating encapsulation 202′) and the second dielectric portion (i.e., the protection layer 310), wherein the through insulator vias 200 is electrically connected to the front-side redistribution circuit layer 204 and the back-side redistribution circuit layer 218. In some embodiments, sidewalls of the through insulator vias 200 are in contact with the first dielectric portion (i.e., the insulating encapsulation 202′) and the second dielectric portion (i.e., the protection layer 310). In some embodiments, an interface is between the first dielectric portion (i.e., the insulating encapsulation 202′) and the second dielectric portion (i.e., the protection layer 310). In some embodiments, the interface between the first dielectric portion (i.e., the insulating encapsulation 202′) and the second dielectric portion (i.e., the protection layer 310) substantially levels with the second surface of the semiconductor substrate 110′.

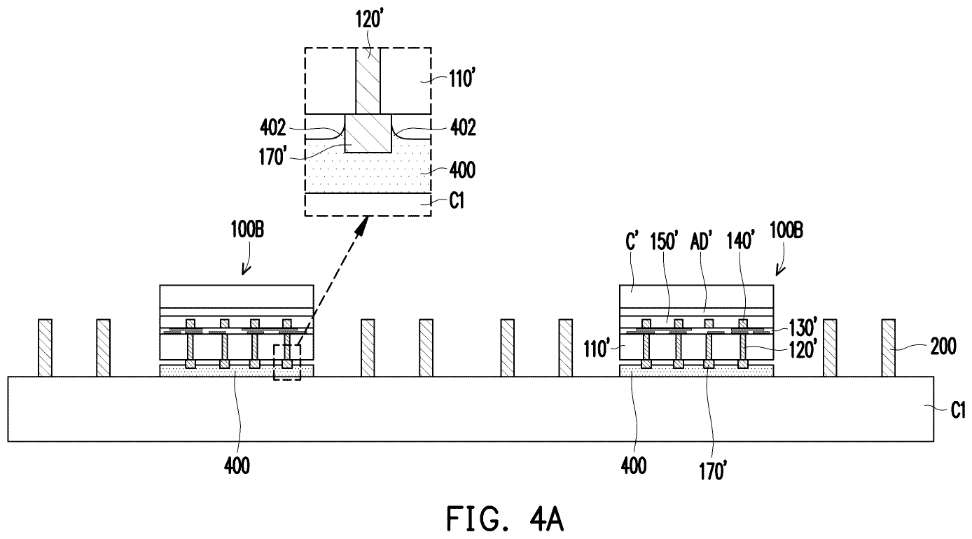

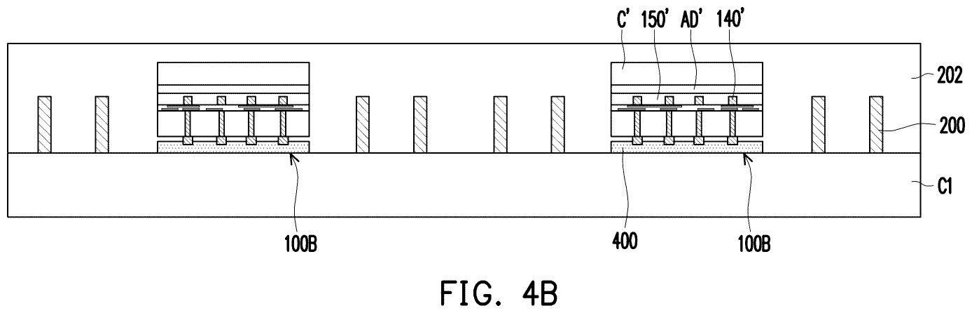

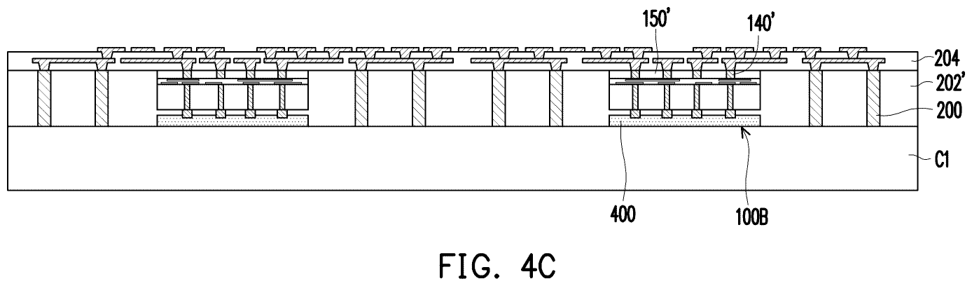

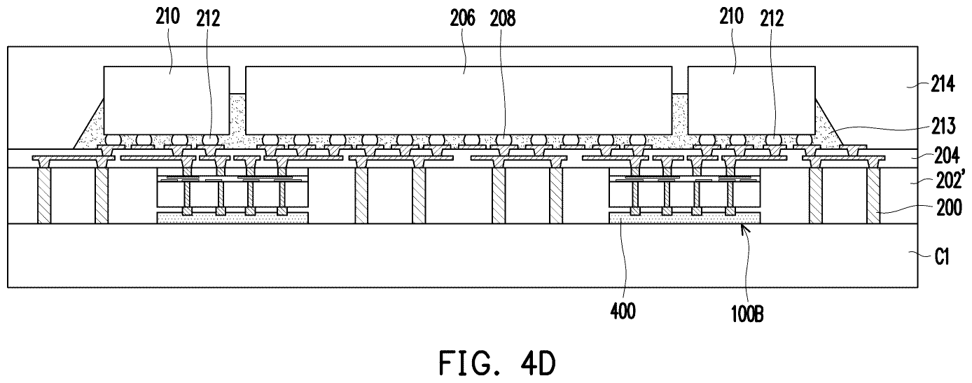

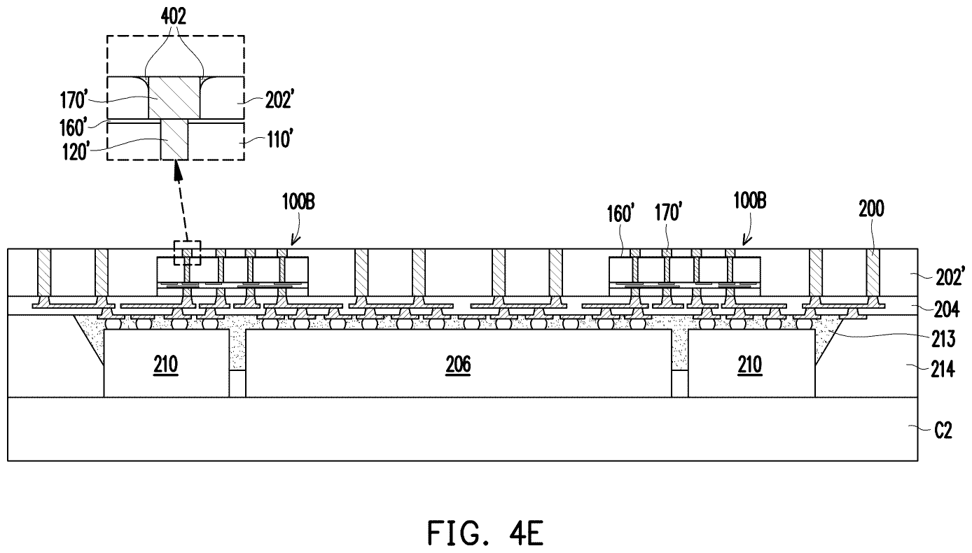

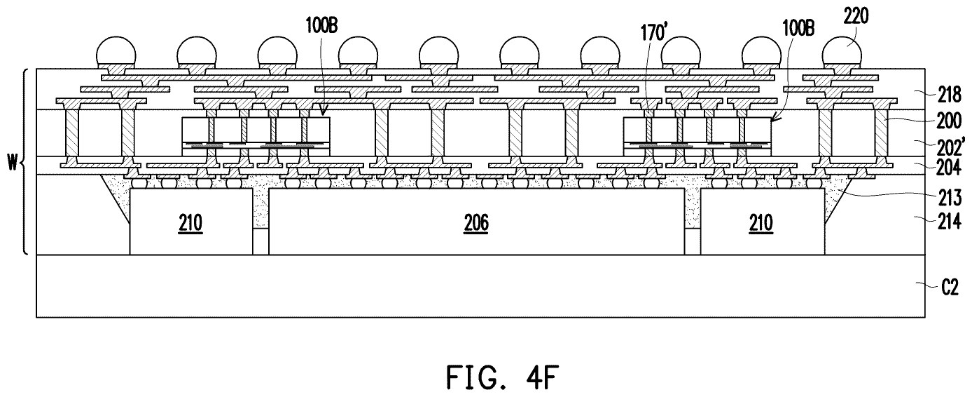

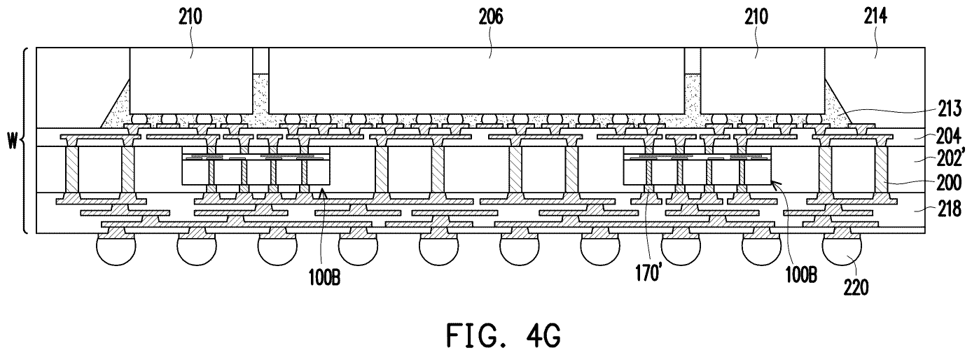

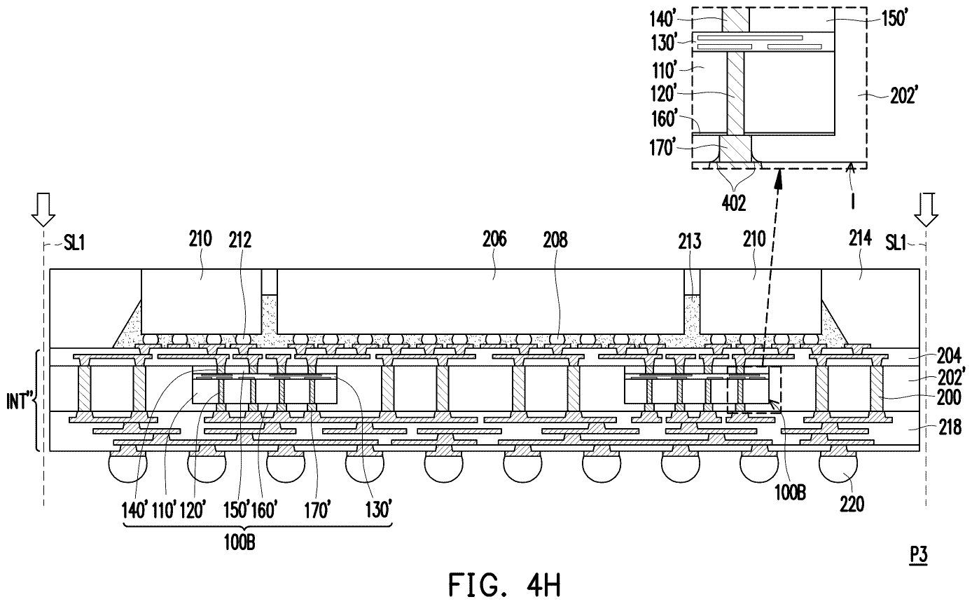

FIG. 4A through FIG. 4H are cross-sectional views schematically illustrating a method illustrating forming a CoWoS package in accordance with some alternative embodiments of the present disclosure.

Referring to FIG. 4A, a carrier C1 is provided. The carrier C1 having die attachment patterns 400 formed thereon is provided. In some embodiments, the carrier C1 is a wafer form glass substrate. The material of the carrier C1 is not limited in the present embodiment. Furthermore, through insulator vias 200 are formed on the carrier C1, and the through insulator vias 200 are laterally spaced apart from the die attachment patterns 400. In some embodiments, the through insulator vias 200 are copper pillars or other conductive pillars. In some embodiments, the through insulator vias 200 may be formed on the carrier C1 through a plating process or other suitable deposition processes. In some other embodiments, the through insulator vias 200 may be pre-formed and placed onto the carrier C1.

After forming the die attachment patterns 400 and the through insulator vias 200, a plurality of local interconnect dies 100B are picked and placed over the die attachment patterns 400 carried by the carrier C1. The local interconnect dies 100B disposed may be arranged side-by-side over the die attachment patterns 400. The local interconnect dies 100B disposed above the die attachment patterns 400 may be substantially identical in thickness. As illustrated in FIG. 4A, the local interconnect dies 100B of the present embodiment is similar to the local interconnect dies 100 as illustrated in FIG. 1E except that the local interconnect dies 100B does not include the protection layer 180′, and the conductive vias 170′ of the local interconnect dies 100B protrude into the die attachment patterns 400. The conductive vias 170′ of the local interconnect dies 100B are partially embedded in and in direct contact with the die attachment patterns 400. As illustrated in FIG. 4A, the conductive vias 170′ of the local interconnect dies 100B protrude into the die attachment patterns 400 and are spaced apart from the carrier C1 by the die attachment patterns 400, and the thickness of the local interconnect dies 100B is greater than the height of the through insulator vias 200. As illustrated in FIG. 4A, gaps are formed between the die attachment patterns 400 and the local interconnect dies 100B at this stage. As illustrated in the enlarged region in FIG. 4A, the die attachment patterns 400 may include protruding portions 402 laterally surrounding the conductive vias 170′. Furthermore, the protruding portions 402 of the die attachment patterns 400 may have tapered sidewalls. Furthermore, the gaps will be filled by the insulating encapsulation 202′ in the process shown in FIG. 4B.

The processes illustrated in FIG. 4B through FIG. 4D are similar to the processes illustrated in FIG. 2B through FIG. 2D, and the details are thus omitted.

Referring to FIG. 2E and FIG. 4E, the process illustrated in FIG. 4E is similar the process illustrated in FIG. 2E except that the die attachment patterns 400 are partially removed until the conductive vias 170′ laterally encapsulated by the insulating encapsulation 202′ are revealed. In some embodiments, as illustrated in FIG. 4E, the protruding portions 402 embedded in the insulating encapsulation 202′ remain after the conductive vias 170′′ are revealed.

The processes illustrated in FIG. 4F through FIG. 4H are similar to the processes illustrated in FIG. 2F through FIG. 2H, and the details are thus omitted.

As illustrated in FIG. 4H, the package structure P3 includes an interposer substrate INT″, a semiconductor die 206 and memory devices 210. The semiconductor die 206 and the memory devices 210 are mounted on and electrically connected to the interposer substrate INT″. The interposer substrate INT″ includes local interconnect dies 100B, a dielectric layer (i.e., the insulating encapsulation 202′), a front-side redistribution circuit layer 204 and a back-side redistribution circuit layer 218. The local interconnect dies 100 each includes a semiconductor substrate 110′, through substrate vias 120′ penetrating through the semiconductor substrate 110, conductive vias 140′, a protection layer 150′ laterally encapsulating the conductive vias 140′, and conductive vias 170′. The conductive vias 140′ and the protection layer 150′ are disposed on a first surface of the semiconductor substrate 110′, and the conductive vias 170′ are disposed on a second surface of the semiconductor substrate 110′. The dielectric layer (i.e., the insulating encapsulation 202′) laterally encapsulates the semiconductor substrate 110′, the protection layer 150′, the protruding portions 402 and the conductive vias 170′, wherein the dielectric layer (i.e., the insulating encapsulation 202′) is in contact with sidewalls of the semiconductor substrate 110′, sidewalls of the protection layer 150′, sidewalls of the conductive vias 170′, the protruding portions 402, and the second surface of the semiconductor substrate 110′. The front-side redistribution circuit layer 204 is electrically connected to the conductive vias 140′. The back-side redistribution circuit layer 218 is electrically connected to the conductive vias 170′, wherein the front-side redistribution circuit layer 204 and the back-side redistribution circuit layer 218 are disposed on opposite sides of the local interconnect dies 100B and the dielectric layer (i.e., the insulating encapsulation 202′). In some embodiments, sidewalls of the front-side redistribution circuit layer substantially align with sidewalls of the dielectric layer (i.e., the insulating encapsulation 202′). In some embodiments, the interposer substrate INT′′ further includes through insulator vias 200 penetrating through the dielectric layer (i.e., the insulating encapsulation 202′), wherein the through insulator vias 200 are electrically connected to the front-side redistribution circuit layer 204 and the back-side redistribution circuit layer 218.

In the above-mentioned embodiments, the back side conductive vias are not covered by a molding compound formed by a molding process, and accordingly, the warpage issue of local interconnect dies can be minimized. Furthermore, since the back-side protection layer is in direct contact with the back-side conductive vias, there is not peeling issue occurred between the back-side protection layer and the back-side conductive vias.

In accordance with some embodiments of the disclosure, an interposer substrate including a local interconnect die, a dielectric layer, a first redistribution circuit layer and a second redistribution circuit layer is provided. The local interconnect die includes a substrate, through vias penetrating through the substrate, first conductive vias, a first protection layer laterally encapsulating the first conductive vias, second conductive vias, and a second protection layer laterally encapsulating the second conductive vias. The first conductive vias and the first protection layer are disposed on a first surface of the substrate. The second conductive vias and the second protection layer are disposed on a second surface of the substrate. The dielectric layer laterally encapsulates the local interconnect die. The first redistribution circuit layer is electrically connected to the first conductive vias. The second redistribution circuit layer is electrically connected to the second conductive vias, wherein the first redistribution circuit layer and the second redistribution circuit layer are disposed on opposite sides of the local interconnect die and the dielectric layer. In some embodiments, sidewalls of the first protection layer substantially align with sidewalls of the substrate, and the sidewalls of the first protection layer laterally offset from sidewalls of the second protection layer. In some embodiments, the sidewalls of the first protection layer and the sidewalls of the substrate includes vertical sidewalls, and the sidewalls of the second protection layer include tapered sidewalls. In some embodiments, a first thickness of the first protection layer is substantially equal to a first height of the first conductive vias, and a second thickness of the second protection layer is substantially equal to a second height of the second conductive vias. In some embodiments, the local interconnect die further includes a planarization layer disposed between the substrate and the second conductive vias, the through vias penetrate through the substrate and the planarization layer, and sidewalls of the planarization layer include tapered sidewalls. In some embodiments, the ring-shaped indentation extends into the substrate. In some embodiments, the depth of the ring-shaped indentation is greater than a sum of the height of the second conductive vias and a thickness of the planarization layer. In some embodiments, the dielectric layer is laterally spaced apart from the second conductive vias by the second protection layer.

In accordance with some other embodiments of the disclosure, an interposer substrate including a local interconnect die, a dielectric layer, a first redistribution circuit layer and a second redistribution circuit layer is provided. The local interconnect die includes a substrate, through vias penetrating through the substrate, first conductive vias, a protection layer laterally encapsulating the first conductive vias, and second conductive vias, the first conductive vias and the protection layer being disposed on a first surface of the substrate, the second conductive vias being disposed on a second surface of the substrate. A first dielectric portion of the dielectric layer laterally encapsulates the substrate and the protection layer, a second dielectric portion of the dielectric layer laterally encapsulates the second conductive vias, and the second dielectric portion is in contact with the second conductive vias and the second surface of the substrate. The first redistribution circuit layer is electrically connected to the first conductive vias. The second redistribution circuit layer is electrically connected to the second conductive vias, wherein the first redistribution circuit layer and the second redistribution circuit layer are disposed on opposite sides of the local interconnect die and the dielectric layer. In some embodiments, the first dielectric portion and the second dielectric portion are different in material. In some embodiments, sidewalls of the first dielectric portion substantially align with sidewalls of the second dielectric portion. In some embodiments, the second dielectric portion is wider than the first protection layer. In some embodiments, sidewalls of the first redistribution circuit layer substantially align with sidewalls of the second dielectric portion. In some embodiments, the interposer substrate further includes a through insulator via penetrating through the first dielectric portion and the second dielectric portion, wherein the through insulator via is electrically connected to the first redistribution circuit layer and the second redistribution circuit layer. In some embodiments, sidewalls of the through insulator via are in contact with the first dielectric portion and the second dielectric portion. In some embodiments, an interface is between the first dielectric portion and the second dielectric portion. In some embodiments, the interface between the first dielectric portion and the second dielectric portion substantially levels with the second surface of the substrate.

In accordance with some other embodiments of the disclosure, an interposer substrate including a local interconnect die, a dielectric layer, a first redistribution circuit layer and a second redistribution circuit layer is provided. The local interconnect die includes a substrate, through vias penetrating through the substrate, first conductive vias, a protection layer laterally encapsulating the first conductive vias, and second conductive vias, the first conductive vias and the protection layer being disposed on a first surface of the substrate, the second conductive vias being disposed on a second surface of the substrate. The dielectric layer laterally encapsulates the substrate, the protection layer and the second conductive vias, wherein the dielectric layer is in contact with sidewalls of the substrate, sidewalls of the protection layer, sidewalls of the second conductive vias, and the second surface of the substrate. The first redistribution circuit layer is electrically connected to the first conductive vias. The second redistribution circuit layer is electrically connected to the second conductive vias, wherein the first redistribution circuit layer and the second redistribution circuit layer are disposed on opposite sides of the local interconnect die and the dielectric layer. In some embodiments, sidewalls of the first redistribution circuit layer substantially align with sidewalls of the dielectric layer. In some embodiments, the interposer substrate further includes through insulator vias penetrating through the dielectric layer, wherein the through insulator vias are electrically connected to the first redistribution circuit layer and the second redistribution circuit layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An interposer substrate, comprising:
an interconnect die comprising a substrate, through vias penetrating through the substrate, first conductive vias, a first protection layer laterally encapsulating the first conductive vias, second conductive vias, and a second protection layer laterally encapsulating the second conductive vias, the first conductive vias and the first protection layer being disposed on a first surface of the substrate, the second conductive vias and the second protection layer being disposed on a second surface of the substrate, wherein the interconnect die comprises a ring-shaped indentation having a depth greater than a height of the second conductive vias;
a dielectric layer laterally encapsulating the interconnect die;
a first redistribution circuit layer electrically connected to the first conductive vias; and
a second redistribution circuit layer electrically connected to the second conductive vias, wherein the first redistribution circuit layer and the second redistribution circuit layer are disposed on opposite sides of the interconnect die and the dielectric layer.

2. The interposer substrate of claim 1, wherein sidewalls of the first protection layer substantially align with sidewalls of the substrate, and the sidewalls of the first protection layer laterally offset from sidewalls of the second protection layer.

3. The interposer substrate of claim 2, wherein the sidewalls of the first protection layer and the sidewalls of the substrate comprises vertical sidewalls, and the sidewalls of the second protection layer comprise tapered sidewalls.

4. The interposer substrate of claim 1, wherein a first thickness of the first protection layer is substantially equal to a first height of the first conductive vias, and a second thickness of the second protection layer is substantially equal to a second height of the second conductive vias.

5. The interposer substrate of claim 1, wherein the interconnect die further comprises a planarization layer disposed between the substrate and the second conductive vias, the through vias penetrate through the substrate and the planarization layer, and sidewalls of the planarization layer comprise tapered sidewalls.

6. The interposer substrate of claim 5, wherein the ring-shaped indentation extends into the substrate.

7. The interposer substrate of claim 5, wherein the depth of the ring-shaped indentation is greater than a sum of the height of the second conductive vias and a thickness of the planarization layer.

8. The interposer substrate of claim 1, wherein the dielectric layer is laterally spaced apart from the second conductive vias by the second protection layer.

9. An interposer substrate, comprising:
an interconnect die comprising a substrate, through vias penetrating through the substrate, first conductive vias, a protection layer laterally encapsulating the first conductive vias, and second conductive vias, the first conductive vias and the protection layer being disposed on a first surface of the substrate, the second conductive vias being disposed on a second surface of the substrate;
a dielectric layer, wherein a first dielectric portion of the dielectric layer laterally encapsulates the substrate and the protection layer, a second dielectric portion of the dielectric layer laterally encapsulates the second conductive vias, and the second dielectric portion is in contact with the second conductive vias and the second surface of the substrate;
a first redistribution circuit layer electrically connected to the first conductive vias; and
a second redistribution circuit layer electrically connected to the second conductive vias, wherein the first redistribution circuit layer and the second redistribution circuit layer are disposed on opposite sides of the interconnect die and the dielectric layer.

10. The interposer substrate of claim 9, wherein the first dielectric portion and the second dielectric portion are different in material.

11. The interposer substrate of claim 9, wherein sidewalls of the first dielectric portion substantially align with sidewalls of the second dielectric portion.

12. The interposer substrate of claim 9, wherein the second dielectric portion is wider than the first protection layer.

13. The interposer substrate of claim 9, wherein sidewalls of the first redistribution circuit layer substantially align with sidewalls of the second dielectric portion.

14. The interposer substrate of claim 9 further comprising:
a through insulator via penetrating through the first dielectric portion and the second dielectric portion, wherein the through insulator via is electrically connected to the first redistribution circuit layer and the second redistribution circuit layer.

15. The interposer substrate of claim 14, wherein sidewalls of the through insulator via are in contact with the first dielectric portion and the second dielectric portion.

16. The interposer substrate of claim 9, wherein an interface is between the first dielectric portion and the second dielectric portion.

17. The interposer substrate of claim 16, wherein the interface between the first dielectric portion and the second dielectric portion substantially levels with the second surface of the substrate.

18. A method, comprising:
providing a semiconductor structure comprising a substrate, through semiconductor vias, an interconnect structure, first conductive vias, and a first protection layer, wherein the through vias penetrate through the substrate, and the first protection layer laterally encapsulates the first conductive vias;
thinning the substrate until the through substrate vias are revealed;
forming second conductive vias on the substrate and the through substrate vias;
forming a second protection layer laterally encapsulating the second conductive vias, wherein the first conductive vias and the first protection layer are disposed on a first surface of the substrate, the second conductive vias and the second protection layer are disposed on a second surface of the substrate; and
performing a singulation process to form interconnect dies, wherein each of the interconnect dies comprises a ring-shaped indentation having a depth greater than a height of the second conductive vias.

19. The method of claim 18, wherein the singulation process comprises a laser grooving process followed by a blade saw process.

20. The method of claim 18, wherein after performing the singulation process, sidewalls of the first protection layer substantially align with sidewalls of the substrate, and the sidewalls of the first protection layer laterally offset from sidewalls of the second protection layer.
